(19) United States
(12) Patent Application Publication
(10) Pub. No.: US 2024/0234398 A1
(43) Pub. Date: Jul. 11, 2024

(54) DISPLAY DEVICE AND METHOD OF FABRICATING DISPLAY DEVICE

(71) Applicant: Samsung Display Co., LTD., Yongin-si (KR)

(72) Inventors: Ki Su JIN, Yongin-si (KR); Gil Tae KANG, Yongin-si (KR); Yun Su GU, Yongin-si (KR); Dong Jun LEE, Yongin-si (KR)

(73) Assignee: Samsung Display Co., LTD., Yongin-si (KR)

(21) Appl. No.: 18/470,476

(22) Filed: Sep. 20, 2023

(30) Foreign Application Priority Data
Jan. 6, 2023 (KR) 10-2023-0002448

(51) Int. Cl. H01L 25/16; H01L 27/12

(52) U.S. Cl. CPC H01L 25/167; H01L 27/1248; H01L 27/1288

(57) ABSTRACT

A display device includes an active area and a peripheral area adjacent to at least a portion of the active area; a base layer; a backplane layer disposed on the base layer; and a light-emitting-element layer disposed on the backplane layer, and including a light emitting element. The backplane layer includes a lower backplane layer, an outer via layer disposed on the lower backplane layer, and an outer passivation layer disposed on the outer via layer. The outer passivation layer includes a first outer passivation layer exposing the outer via layer through a hole in the active area, and a second outer passivation layer not exposing the outer via layer in the peripheral area.

### CROSS-REFERENCE TO RELATED APPLICATION(S)

This application claims priority to and benefits of Korean patent application No. 10-2023-0002448 under 35 U.S.C. § 119 filed on Jan. 6, 2023 in the Korean Intellectual Property Office, the entire contents of which are incorporated herein by reference.

### BACKGROUND

### 1. Technical Field

Various embodiments relate to a display device and a method of fabricating the display device.

### 2. Description of the Related Art

Recently, as interest in information display increases, research and development on display devices have been continuously conducted.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Various embodiments are directed to a display device capable of eliminating a risk caused by outgassing, and capable of preventing a residue phenomenon from occurring due to remnants of a structure used during a process of fabricating the display device, and directed to a method of fabricating the display device.

The technical objectives to be achieved by the disclosure are not limited to those described herein, and other technical objectives that are not mentioned herein would be clearly understood by a person skilled in the art from the description of the disclosure.

An embodiment may provide a display device that may comprise an active area and a peripheral area adjacent to at least a portion of the active area. The display device may comprise a base layer; a backplane layer disposed on the base layer; and a light-emitting-element layer disposed on the backplane layer, and comprising a light emitting element. The backplane layer may comprise a lower backplane layer, an outer via layer disposed on the lower backplane layer, and an outer passivation layer disposed on the outer via layer. The outer passivation layer may comprise a first outer passivation layer exposing the outer via layer through a hole in the active area, and a second outer passivation layer not exposing the outer via layer in the peripheral area.

In an embodiment, the second outer passivation layer may be disposed in a peripheral cover area. A portion of the peripheral cover area may overlap the peripheral area, in a plan view, and another portion of the peripheral cover area may overlap the active area, in a plan view.

In an embodiment, the second outer passivation layer may comprise a body covering an overall surface of the peripheral area, and an extension part extending from the body and disposed in the active area.

In an embodiment, the peripheral cover area may be formed along an edge of the display device.

In an embodiment, a width of the peripheral cover area may be in a range of about 100 μm to about 800 μm.

In an embodiment, the lower backplane layer may comprise a lower via layer, and a lower passivation layer disposed on the lower via layer. Each of the outer passivation layer and the lower passivation layer may comprise an inorganic material. Each of the outer via layer and the lower via layer may comprise an organic material. The lower passivation layer may form a lower hole exposing the lower via layer.

An embodiment may provide a method of fabricating a display device that may comprise fabricating cells including forming a backplane layer on a substrate; forming an ink layer on the backplane layer; and separating the cells from each other. Each of the cells may comprise an internal area, and a peripheral area adjacent to at least a portion of the internal area. Forming the backplane layer may comprise forming an outer via layer, and forming an outer passivation layer on the outer via layer. Forming the outer passivation layer may comprise forming a first outer passivation layer, and forming a second outer passivation layer. Forming the first outer passivation layer may comprise forming a hole exposing the outer via layer, in the first outer passivation layer in the internal area. Forming the second outer passivation layer may comprise covering the outer via layer with the second outer passivation layer without exposing the outer via layer in the peripheral area.

In an embodiment, the second outer passivation layer may cover an overall surface of the peripheral area.

In an embodiment, the peripheral area may correspond to an edge of each of the cells.

In an embodiment, the ink layer may comprise an end based on a direction from the internal area toward the peripheral area. The end may overlap the peripheral area, in a plan view.

In an embodiment, the end may not contact the outer passivation layer in the peripheral area, and may contact the second outer passivation layer.

In an embodiment, the end may contact the outer passivation layer in the hole in the internal area.

In an embodiment, the ink layer may comprise an acrylic oligomer.

In an embodiment, the method may further comprise removing the ink layer; and forming a film layer on the outer passivation layer.

In an embodiment, the separating of the cells from each other may comprise forming a base layer of each of the cells by the substrate. Forming the backplane layer may comprise forming a first backplane layer on a surface of the base layer, and forming a second backplane layer on a rear surface of the base layer. The method may further comprise forming a light-emitting-element layer comprising a light emitting element on the first backplane layer. The first backplane layer may comprise a pad and a pixel circuit configured to drive the light emitting element. The second backplane layer may comprise a line that electrically connects a driving circuit component with the pad.

In an embodiment, the forming of the ink layer may comprise forming a first ink layer on the first backplane layer, and forming a second ink layer on the second backplane layer. The method may further comprise removing the first ink layer and forming the first film layer on the first backplane layer; and removing the second ink layer and forming a second film layer on the second backplane layer.

In an embodiment, the first film layer and the second film layer may package a stacked structure comprising the first backplane layer and the second backplane layer.

An embodiment may provide a method of fabricating a display device, comprising fabricating cells, including forming a backplane layer on a substrate; forming a film layer on the backplane layer; forming an ink layer on the film layer; and separating the cells from each other. Forming the backplane layer may comprise forming an outer via layer, and forming an outer passivation layer on the outer via layer. Forming the outer passivation layer may comprise forming a hole, exposing the outer via layer, in the outer passivation layer. Forming the film layer may comprise covering an entirety of the hole with the film layer.

In an embodiment, the film layer may form a base surface that disposes the ink layer on the base surface. The ink layer may be separated from the backplane layer by the film layer.

In an embodiment, each of the cells may comprise an internal area and a peripheral area. The hole may comprise an internal hole disposed in the internal area, and a peripheral hole disposed in the peripheral area.

### BRIEF DESCRIPTION OF THE DRAWINGS

The above and other objects and features of the present disclosure will become apparent by describing in detail embodiments thereof with reference to the accompanying drawings. in which:

FIG. 1 is a schematic plan view illustrating a display device in accordance with an embodiment.

FIG. 2 is a schematic plan view illustrating a pixel in accordance with an embodiment.

FIG. 3 is a schematic cross-sectional view illustrating a display device in accordance with an embodiment.

FIG. 4 is a schematic cross-sectional view illustrating a first backplane layer in accordance with an embodiment.

FIG. 5 is a schematic cross-sectional view taken along line A-A′ of FIG. 1.

FIG. 6 is a schematic plan view illustrating an outer passivation layer and an outer via layer in accordance with an embodiment.

FIG. 7 is a schematic cross-sectional view taken along line B-B′ of FIG. 1.

FIG. 8 is a flowchart illustrating a method of fabricating the display device in accordance with an embodiment.

FIGS. 9, 11, and 13 are schematic plan views illustrating, by process steps, a method of fabricating the display device in accordance with an embodiment.

FIGS. 10, 12, 14, and 15 are schematic cross-sectional views illustrating, by process steps, a method of fabricating the display device in accordance with an embodiment.

FIG. 16 is a flowchart illustrating a method of fabricating the display device in accordance with an embodiment.

FIGS. 17 to 24 are schematic cross-sectional views illustrating, by process phases, a method of fabricating the display device in accordance with an embodiment.

FIG. 25 is a flowchart illustrating a method of fabricating the display device in accordance with an embodiment.

FIG. 26 is a schematic cross-sectional view illustrating processing steps of the method of fabricating the display device in accordance with an embodiment.

### DETAILED DESCRIPTION OF THE EMBODIMENTS

As the disclosure allows for various changes and numerous embodiments, embodiments will be illustrated in the drawings and described in detail in the written description. However, this is not intended to limit the disclosure to particular modes of practice, and it is to be appreciated that all changes, equivalents, and substitutes within the spirit and technical scope of the disclosure are encompassed herein.

In the drawings, sizes, thicknesses, ratios, and dimensions of the elements may be exaggerated for ease of description and for clarity. Like numbers refer to like elements throughout.

It will be understood that, although the terms “first”, “second”, etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.

It will be further understood that the terms “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Furthermore, in case that a first part such as a layer, a film, a region, or a plate is disposed on a second part, the first part may be not only directly on the second part but a third part or other parts may intervene between them. When it is expressed that a first part such as a layer, a film, a region, or a plate is formed on a second part, the surface of the second part on which the first part is formed is not limited to an upper surface of the second part but may comprise other surfaces such as a side surface or a lower surface of the second part. To the contrary, in case that a first part such as a layer, a film, a region, or a plate is under or below a second part, the first part may be not only directly under or below the second part but a third part or other parts may intervene between them.

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. The term “overlap” or “overlapped” means that a first object may be above or below or to a side of a second object, and vice versa.

Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It is also to be understood that terms defined in commonly used dictionaries should be interpreted as having meanings consistent with the meanings in the context of the related art, and are expressly defined herein and should not be interpreted in an ideal or overly formal sense unless so defined or implied herein.

Various embodiments relate to a display device and a method of fabricating the display device. Hereinafter, a display device and a method of fabricating the display device in accordance with an embodiment will be described with reference to the attached drawings.

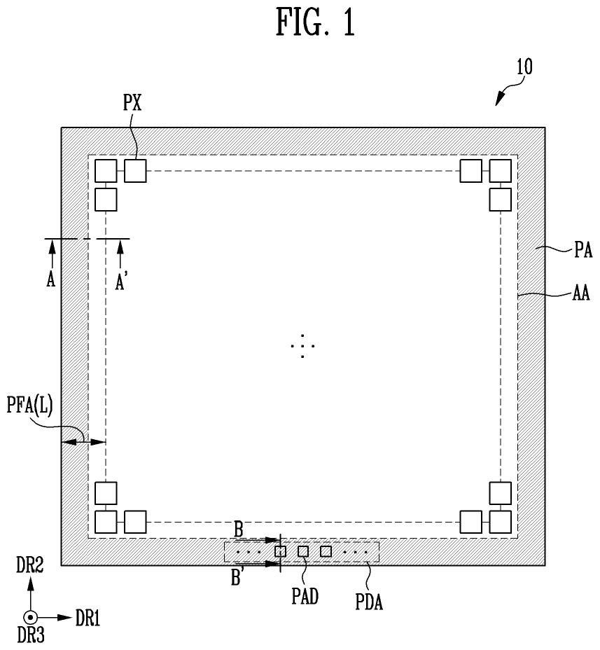

Hereinafter, a display device 10 in accordance with an embodiment will be described with reference to FIGS. 1 to 7.

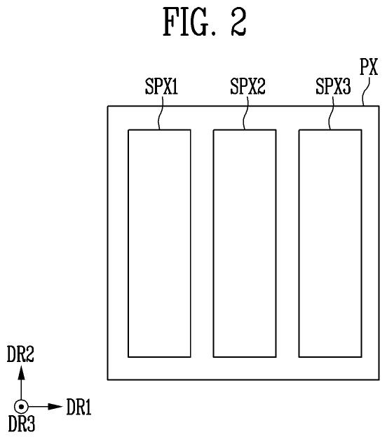

FIG. 1 is a schematic plan view illustrating the display device 10 in accordance with an embodiment. FIG. 2 is a schematic plan view illustrating a pixel PX in accordance with an embodiment.

Referring to FIG. 1, the display device 10 may output optical information. For example, the display device 10 may be a device configured to display a video or a static image. The display device 10 may be used not only as portable electronic devices such as a mobile phone, a smart phone, a tablet personal computer (a table PC), a smart watch, a watch phone, a mobile communication terminal, an electronic notebook, an electronic book, a portable multimedia player (PMP), a navigation device, and an ultra mobile PC (UMPC), but also as display screens of various products such as a television, a notebook, a monitor, an advertisement panel, and an internet of tings (IOT). Here, the application field of the display device 10 is not limited to a specific example.

The display device 10 may be formed of a rectangular panel having long sides extending in a first direction DR1, and short sides extending a second direction DR2 intersecting the first direction DR1. Corners where the long sides extending in the first direction DR1 and the short sides extending in the second direction DR2 meet may be rounded with a selectable curvature or may be formed at a substantially right angle. The plane shape of the display device 10 is not limited to a rectangular shape, and may have other polygonal shapes, a circular shape, or an elliptical shape. The display device 10 may be formed to be planar, but it is not limited thereto. For example, the display device 10 may comprise a curved surface which is formed on each of left and right side edges thereof and has a constant curvature or a varying curvature. The display device 10 may be formed to be flexible so that the display device 10 can be bent, curved, folded, or rolled.

The display device 10 may comprise an active area AA and a peripheral area PA. The display device 10 may comprise a peripheral cover area PFA. The display device 10 may comprise a pad area PDA.

The active area AA may be an area in which a pixel PX is disposed. The active area AA may be a display area. The active area AA may be an area in which a light emitting element LE is disposed. For example, the active area AA may overlap the pixel PX (or the light emitting element LE), in a plan view.

The peripheral area PA may comprise an area other than the active area AA. The peripheral area PA may refer to an area in which the pixel PXL is not disposed. A pad PAD and a line electrically connected to the pixel PX may be disposed in the peripheral area PA. The peripheral area PA may be a non-display area. The peripheral area PA may comprise a pad area PDA in which the pad PAD is disposed.

The display device 10 may comprise a pad PAD disposed in the pad area PDA. The pad PAD may be disposed on one side or a side of the active area AA. However, the disclosure is not particularly limited.

The peripheral cover area PFA may comprise a portion of the peripheral area PA. The peripheral cover area PFA may be formed in the perimeter of the display device 10. The peripheral cover area PFA may have a width corresponding to a cover length L from an edge of the display device 10. The peripheral cover area PFA may overlap the pad area PDA. In an embodiment, the cover length L may be about 800 μm or less. For example, the cover length L may be in a range of about 100 μm to about 800 μm or less. In an embodiment, the cover length L may be about 500 μm or less. However, the disclosure is not limited to the foregoing examples.

The peripheral cover area PFA may comprise a portion of the active area AA. For example, the peripheral cover area PFA may overlap the pixel PX, in a plan view. The peripheral cover area PFA may overlap the light emitting element LE, in a plan view.

The peripheral cover area PFA may be formed along the edge of the display device 10. The peripheral cover area PFA may overlap the outermost edge of the display device 10.

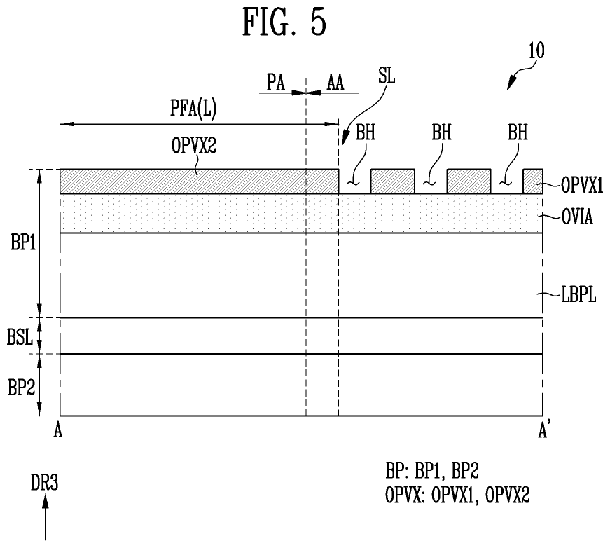

The peripheral cover area PFA may be an area where a second outer passivation layer OPVX2 (refer to FIG. 5) capable of covering the overall surface of the peripheral area PA is disposed. Detailed description pertaining to the foregoing will be made below.

The display device 10 may further comprise pixels PX configured to display an image, scan lines extending in the first direction DR1, and data lines extending in the second direction DR2. The pixels PX may be arranged or disposed in the form of a matrix in the first direction DR1 and the second direction DR2.

Each of the pixels PX may comprise sub-pixels SPX1, SPX2, and SPX3, as illustrated in FIG. 2. Although FIG. 2 illustrates that each of the pixels PX comprises three sub-pixels SPX1, SPX2, and SPX3, for example, a first sub-pixel SPX1, a second sub-pixel SPX2, and a third sub-pixel SPX3, the disclosure is not limited thereto.

The first sub-pixel SPX1, the second sub-pixel SPX2, and the third sub-pixel SPX3 may be connected to at least one data line among the data lines and at least one scan line among the scan lines.

Each of the first sub-pixel SPX1, the second sub-pixel SPX2, and the third sub-pixel SPX3 may have a rectangular shape, a square shape, or a rhombus shape, in a plan view. For example, each of the first sub-pixel SPX1, the second sub-pixel SPX2, and the third sub-pixel SPX3 may have a rectangular planar shape having short sides extending in the first direction DR1 and long sides extending in the second direction DR2, as illustrated in FIG. 2. In an embodiment, each of the first sub-pixel SPX1, the second sub-pixel SPX2, and the third sub-pixel SPX3 may have a square or rhombus planar shape having sides having the same length in the first direction DR1 and the second direction DR2.

As illustrated in FIG. 2, the first sub-pixel SPX1, the second sub-pixel SPX2, and the third sub-pixel SPX3 may be arranged or disposed in the first direction DR1. The first sub-pixel SPX1 and any one of the second sub-pixel SPX2 and the third sub-pixel SPX3 may be arranged or disposed in the first direction DR1, and a remaining one and the first sub-pixel SPX1 may be arranged or disposed in the second direction DR2.

The second sub-pixel SPX2 and any one of the first sub-pixel SPX1 and the third sub-pixel SPX3 may be arranged or disposed in the first direction DR1, and a remaining one and the second sub-pixel SPX1 may be arranged or disposed in the second direction DR2. As another example, the third sub-pixel SPX3 and any one of the first sub-pixel SPX1 and the second sub-pixel SPX2 may be arranged or disposed in the first direction DR1, and a remaining one and the third sub-pixel SPX3 may be arranged or disposed in the second direction DR2.

The first sub-pixel SPX1 may emit a first color of light. The second sub-pixel SPX2 may emit a second color of light. The third sub-pixel SPX3 may emit a third color of light. Here, the first color may be light in a red wavelength band. The second color may be light in a green wavelength band. The third color may be light in a blue wavelength band. The red wavelength band may be a wavelength band ranging from about 600 nm to about 750 nm. The green wavelength band may be a wavelength band ranging from about 480 nm to about 560 nm. The blue wavelength band may be a wavelength band ranging from about 370 nm to about 460 nm. However, embodiments are not limited to the foregoing.

Each of the first sub-pixel SPX1, the second sub-pixel SPX2, and the third sub-pixel SPX3 may comprise a light emitting element LE configured to emit light.

The light emitting element LE may be provided in various shapes. For example, the light emitting element LE may be an inorganic light emitting element comprising inorganic material. In an embodiment, the light emitting element LE may be an organic light emitting diode (OLED). However, the disclosure is not limited to a particular example. Hereinafter, for convenience of explanation, description will be made based on an embodiment in which the light emitting element LE is a flip-chip-type micro light emitting diode (LED) as an inorganic light emitting element comprising an inorganic semiconductor.

As illustrated in FIG. 2, the surface area of the first sub-pixel SPX1, the surface area of the second sub-pixel SPX2, and the surface area of the third sub-pixel SPX3 may be substantially the same as each other, but the disclosure is not limited thereto. At least any one of the surface area of the first sub-pixel SPX1, the surface area of the second sub-pixel SPX2, and the surface area of the third sub-pixel SPX3 may be different from another one. Any two of the surface area of the first sub-pixel SPX1, the surface area of the second sub-pixel SPX2, and the surface area of the third sub-pixel SPX3 may be substantially the same as each other, and a remaining one may be different from the two. The surface area of the first sub-pixel SPX1, the surface area of the second sub-pixel SPX2, and the surface area of the third sub-pixel SPX3 may be different from each other.

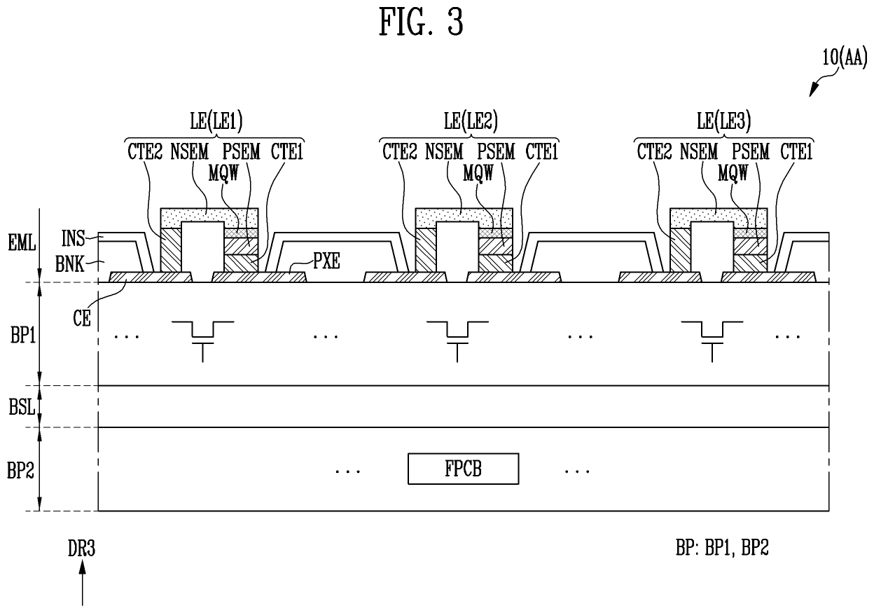

FIG. 3 is a schematic cross-sectional view illustrating a display device 10 in accordance with an embodiment. FIG. 3 schematically illustrates a cross-sectional structure of the display device 10 in the active area AA.

Referring to FIG. 3, the display device 10 may comprise a base layer BSL, a backplane layer BP, and a light-emitting-element layer EML.

The base layer BSL may be a base substrate or a base component for supporting the display device 10. The base layer BSL may be a rigid substrate made of glass. The base layer BSL may be a flexible substrate which can be bent, folded, or rolled. The substrate may comprise insulating material such as polymer resin, for example, polyimide.

The backplane layer BP may comprise a substrate, metal layers provided to form pixel circuits and lines, and insulating layers disposed between the metal layers.

The backplane layer BP may comprise a first backplane layer BP1 comprising a pixel circuit configured to drive light emitting elements LE, and a second backplane layer BP2 comprising lines that are electrically connected to a driving circuit component FPCB.

The pixel circuits each may comprise a thin film transistor. The pixel circuits each may further comprise a storage capacitor. The pixel circuits may be electrically connected to the light emitting elements LE, and may provide electrical signals allowing the light emitting elements LE to emit light.

The first backplane layer BP1 may be disposed between the base layer BSL and the light-emitting-element layer EML. The second backplane layer BP2 may be disposed on a rear surface of the base layer BSL. In an embodiment, lines formed on the second backplane layer BP2 may electrically connect the driving circuit component FPCB with the pads PAD. For example, the second backplane layer BP2 may comprise lines for electrically connecting the driving circuit component FPCB with the pads PAD.

The light-emitting-element layer EML may be disposed on the backplane layer BP (for example, the first backplane layer BP1). The light-emitting-element layer EML may comprise pixel electrodes PXE, common electrodes CE, and light emitting elements LE. The first sub-pixel SPX1, the second sub-pixel SPX2, and the third sub-pixel SPX3 each may comprise a light emitting element LE connected to the corresponding pixel electrode PXE and the corresponding common electrode CE. In an embodiment, the light emitting elements LE may comprise a first light emitting element LE1 configured to emit a first color of light and comprised in the first sub-pixel SPX1, a second light emitting element LE2 configured to emit a second color of light and comprised in the second sub-pixel SPX2, and a third light emitting element LE3 configured to emit a third color of light and comprised in the third sub-pixel SPX3. The pixel electrode PXE may be referred to as an anode electrode. The common electrode CE may be referred to as a cathode electrode.

The pixel electrodes PXE and the common electrodes CE may be disposed on the backplane layer BP. Each of the pixel electrodes PXE may be electrically connected to a thin film transistor of the backplane layer BP. Therefore, a pixel voltage or an anode voltage which is controlled by the thin film transistor may be applied to the pixel electrode PXE.

Each of the common electrodes CE may be electrically connected to a power line formed in the backplane layer BP. Hence, a power voltage of the power line may be applied to the common electrodes CE.

The pixel electrodes PXE and the common electrodes CE may comprise metallic material, such as a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO, having relatively high reflectivity. The APC alloy may be an alloy of silver (Ag), palladium (Pd), and copper (Cu).

FIG. 3 illustrates that each of the light emitting elements LE is a flip-chip-type micro LED in which a first contact electrode CTE1 and a second contact electrode CTE2 are disposed to face the pixel electrode PXE and the common electrode CE. However, the shape of the light emitting element LE is not limited to the foregoing.

The light emitting element LE may comprise inorganic material such as GaN. The light emitting element LE may range from several μm to several hundred μm in length in each of a first direction DR1, a second direction DR2, and a third direction DR3. For example, the light emitting element LE may have a length of about 100 μm or less in each of the first direction DR1, the second direction DR2, and the third direction DR3.

Each of the light emitting elements LE may be a light emitting structure comprising an n-type semiconductor NSEM, an active layer MQW, a p-type semiconductor PSEM, a first contact electrode CTE1, and a second contact electrode CTE2.

A portion of the n-type semiconductor NSEM may be disposed on the active layer MQW. A portion of the n-type semiconductor NSEM may be disposed on the second contact electrode CTE2. In an embodiment, one surface or a surface of the n-type semiconductor NSEM may face a display surface. The n-type semiconductor NSEM may be formed of GaN doped with an n-type conductive dopant such as Si, Ge, and Sn. However, the disclosure is not limited thereto.

The active layer MQW may be disposed on a first portion of one surface or a surface of the n-type semiconductor NSEM. The active layer MQW may be interposed between the n-type semiconductor NSEM and the p-type semiconductor PSEM. The active layer MQW may comprise material having a single or multiple quantum well structure. In the case in which the active layer MQW comprises material having a multiple quantum well structure, the active layer MQW may have a structure formed by alternately stacking well layers and barrier layers each other. Here, although the well layer may be formed of InGaN and the barrier layer may be formed of GaN or AlGaN, the disclosure is not limited thereto. The active layer MQW may have a structure formed by alternately stacking each other semiconductor materials having large band gap energy and semiconductor materials having small band gap energy, and may comprise group-3 to -5 semiconductor materials depending on the wavelength band of light to be emitted.

The p-type semiconductor PSEM may be disposed on one surface or a surface of the active layer MQW. The p-type semiconductor PSEM may be formed of GaN doped with a p-type conductive dopant such as Mg, Zn, Ca, Se, and Ba. However, the disclosure is not limited thereto.

The first contact electrode CTE1 may be disposed on the p-type semiconductor PSEM. The second contact electrode CTE2 may be disposed on a second portion of the one surface or a surface of the n-type semiconductor NSEM. The second portion of the one surface or a surface of the n-type semiconductor NSEM on which the second contact electrode CTE2 is disposed may be disposed at a position spaced apart from the first portion of the one surface or a surface of the n-type semiconductor NSEM on which the active layer MQW is disposed.

The first contact electrode CTE1 and the pixel electrode PXE may adhere to each other by an anisotropic conductive film (ACF) or conductive adhesive such as anisotropic conductive paste (ACP). The first contact electrode CTE1 and the pixel electrode PXE may adhere to each other through a soldering process.

A bank BNK may be disposed on the backplane layer BP such that an edge of the pixel electrode PXE and an edge of the common electrode CE are covered with the bank BNK. The bank BNK may be formed of an organic layer made of, for example, acryl resin, epoxy resin, phenolic resin, polyamide resin, polyimide resin, or the like within the spirit and the scope of the disclosure.

The insulating layer INS may be disposed on the bank BNK. The insulating layer INS may cover the edge of the pixel electrode PXE and the edge of the common electrode CE. The insulating layer INS may be formed of an inorganic layer, for example, a silicon nitride layer, a silicon oxynitride layer, a silicon oxide layer, a titanium oxide layer, or an aluminum oxide layer.

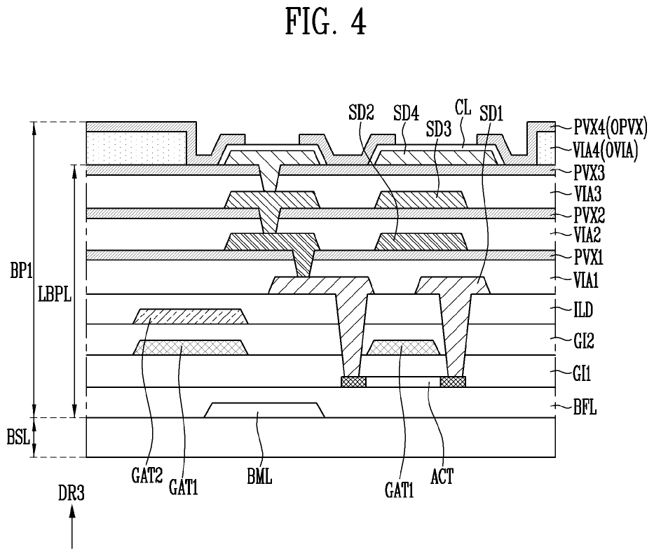

FIG. 4 is a schematic cross-sectional view illustrating the first backplane layer BP1 in accordance with an embodiment. FIG. 4 illustrates an example of the structure of the first backplane layer BP1.

Referring to FIG. 4, the first backplane layer BP1 may be disposed on the base layer BSL, and may comprise a lower backplane layer LBPL, and an outer structure disposed on the lower backplane layer LBPL.

The lower backplane layer LBPL may embrace conductive layers and insulating layers which are disposed between the base layer BSL and the outer structure disposed in the outermost portion of the first backplane layer BP1.

The lower backplane layer LBPL may have a shape formed by patterning at least a portion of a structure in which a bottom auxiliary-electrode layer BML, a buffer layer BFL, an active layer ACT, a first gate insulating layer GI1, a first gate electrode GAT1, a second gate insulating layer GI2, a second gate electrode layer GAT2, an interlayer insulating layer ILD, a first interlayer conductive layer SD1, a first via layer VIA1, a first passivation layer PVX1, a second interlayer conductive layer SD2, a second via layer VIA2, a second passivation layer PVX2, a third interlayer conductive layer SD3, a third via layer VIA3, and a third passivation layer PVX3 may be successively stacked each other.

For example, the above-mentioned electrode layers may be patterned according to one structure, thus forming a pixel circuit. For example, a portion of the active layer ACT, a portion of the first gate electrode GAT1, and a portion of the first interlayer conductive layer SD1 may form a driving transistor structure.

In an embodiment, the first buffer layer BFL, the first gate insulating layer GI1, the second gate insulating layer GI2, the interlayer insulating layer ILD, and the first to third passivation layers PVX1 to PVX3 may comprise inorganic material. In an embodiment, each of the first to third passivation layers PVX1 to PVX3 may form a hole through which the corresponding via layer disposed thereunder is exposed. For example, the first passivation layer PVX1 may form a hole through which the first via layer VIA1 is exposed. The second passivation layer PVX2 may form a hole through which the second via layer VIA2 is exposed. The third passivation layer PVX3 may form a hole through which the third via layer VIA3 is exposed. Each of the holes may form an out-gassing path through which gas can be exhausted from the backplane layer BP.

In an embodiment, the active layer ACT may be a semiconductor. For example, the active layer ACT may comprise at least one selected from the group consisting of polysilicon, low temperature polycrystalline silicon (LTPS), amorphous silicon, and an oxide semiconductor.

In an embodiment, the first to third via layers VIA1 to VIA3 may comprise organic material.

In an embodiment, the bottom auxiliary-electrode layer BML, the first and second gate electrode layers GAT1 and GAT2, and the first to third interlayer conductive layers SD1 to SD3 may comprise conductive material.

The numbers and materials of conductive layers and insulating layers that form the lower backplane layer LBPL are not particularly limited to the foregoing example, and the numbers and materials of conductive layers and insulating layers may be changed in various ways.

The outer structure disposed on the lower backplane layer LBPL may comprise an outer via layer OVIA (VIA4) and an outer passivation layer OPVX (PVX4). In an embodiment, the outer structure may comprise a fourth interlayer conductive layer SD4 and a conductive connection layer CL.

In an embodiment, the fourth interlayer conductive layer SD4 and the conductive connection layer CL may comprise conductive material. In an embodiment, the conductive connection layer CL may comprise transparent electrode (for example, indium tin oxide (ITO)), but the disclosure is not limited thereto.

The outer via layer OVIA may comprise organic material. The outer passivation layer OPVX may comprise inorganic material. The outer passivation layer OPVX may cover the outer via layer OVIA. In an embodiment, the outer passivation layer OPVX allows a portion of the conductive connection layer CL to be exposed.

In an embodiment, the organic material may comprise one or more selected from the group consisting of acrylic resin, epoxy resin, phenol resin, polyamide resin, polyimide resin, polyester resin, polyphenylene sulfide resin, and benzocyclobutene. However, the disclosure is not limited to the foregoing.

In an embodiment, the inorganic material may comprise one or more selected from the group consisting of silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), and silicon oxynitride (SiOₓN_{y}). However, the disclosure is not limited to the foregoing.

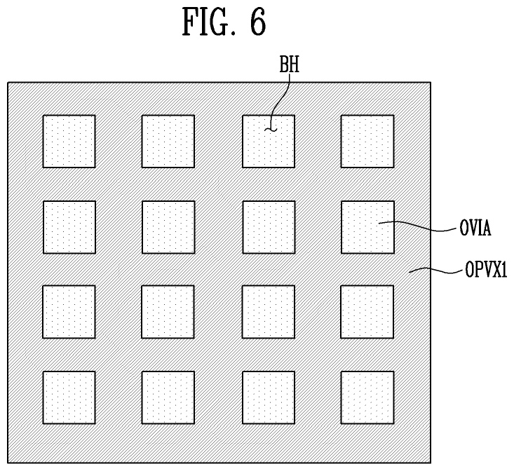

The structure of the outer passivation layer OPVX and the outer via layer OVIA in accordance with an embodiment will be described with reference to FIGS. 5 and 6.

FIG. 5 is a schematic cross-sectional view taken along line A-A′ of FIG. 1. FIG. 5 schematically illustrates areas adjacent to the edge of the display device 10. FIG. 5 illustrates the base layer BSL and the backplane layer BP without illustrating the light-emitting-element layer EML, for convenience of explanation.

FIG. 6 is a schematic plan view illustrating the outer passivation layer OPVX and the outer via layer OVIA in accordance with an embodiment. FIG. 6 schematically illustrates a planar structure of the outer passivation layer OPVX and the outer via layer OVIA.

Referring to FIGS. 5 and 6, the first backplane layer BP1 comprising the lower backplane layer LBPL may be formed on one surface or a surface of the base layer BSL. The second backplane layer BP2 may be formed on the other surface of the base layer BSL.

The outer via layer OVIA may be disposed on the peripheral area PA and the active area AA. For example, the outer via layer OVIA may overlap the peripheral area PA, in a plan view. The outer via layer OVIA may overlap the active area AA, in a plan view.

The outer via layer OVIA may comprise organic material. Gas formed in the first backplane layer BP1 may pass through the outer via layer OVIA.

The outer via layer OVIA may be exposed through a hole BH. For example, the outer via layer OVIA may not be covered by the outer passivation layer OPVX in an area corresponding to the hole BH. In an embodiment, the hole BH may form an out-gassing path for exhausting gas.

The outer passivation layer OPVX may be disposed on the outer via layer OVIA. The outer passivation layer OPVX may comprise a first outer passivation layer OPVX1 and a second outer passivation layer OPVX2.

The first outer passivation layer OPVX1 and the second outer passivation layer OPVX2 may be spaced apart from each other. For example, a separation line SL for distinguishing positions of the first outer passivation layer OPVX1 and the second outer passivation layer OPVX2 from each other may overlap the active area AA.

The first outer passivation layer OPVX1 may be disposed in the active area AA. The first outer passivation layer OPVX1 may not be disposed in the peripheral area PA. The first outer passivation layer OPVX1 allows the outer via layer OVIA in the active area AA to be exposed. For example, the first outer passivation layer OPVX1 may form the hole BH. The first outer passivation layer OPVX1 allows the outer via layer OVIA to be exposed through the hole BH in the active area AA.

The hole BH may comprise holes. The hole BH may have at least one shape or a shape selected from the group consisting of a circular shape, an elliptical shape, and a polygonal shape. The shape and arrangement structure of the hole BH are not particularly limited.

In an embodiment, the hole BH may comprise a first hole formed by the first outer passivation layer OPVX1, and a second hole formed by the first outer passivation layer OPVX1 and the second outer passivation layer OPVX2.

At least a portion of the second outer passivation layer OPVX2 may be disposed in the peripheral area PA. At least a portion of the second outer passivation layer OPVX2 may be disposed in the active area AA. The second outer passivation layer OPVX2 may overlap the peripheral area PA, in a plan view. The second outer passivation layer OPVX2 may further overlap the active area AA, in a plan view. The second outer passivation layer OPVX2 may comprise a body disposed in the peripheral area PA, and an extension part which extends from the body and is disposed in the active area AA. In an embodiment, the extension part of the second outer passivation layer OPVX2 may be spaced apart from the first outer passivation layer OPVX1 with the hole BH interposed therebetween.

In an embodiment, the second outer passivation layer OPVX2 may cover an overall surface of the peripheral area PA. The second outer passivation layer OPVX2 may prevent the outer via layer OVIA in the peripheral area PA from being exposed. The second outer passivation layer OPVX2 covers an overall surface of the outer via layer OVIA in the peripheral area PA so that, during a process of fabricating the display device 10, a residue risk attributable to processing remnants in the peripheral area PA can be prevented from being caused. Detailed description pertaining to the foregoing will be made below.

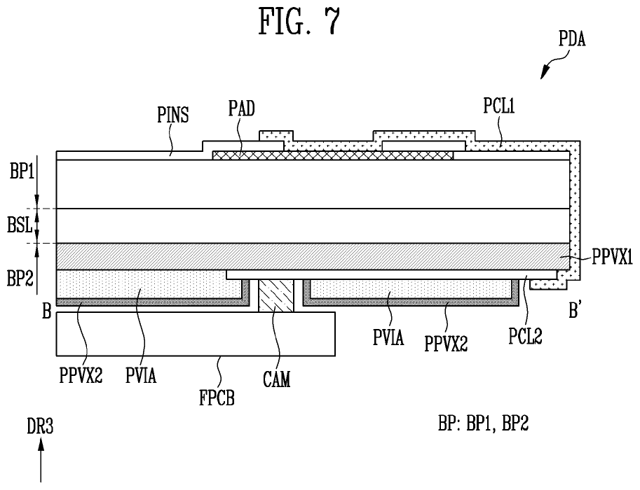

A cross-sectional structure of the display device 10 in the pad area PDA in accordance with an embodiment will be described with reference to FIG. 7.

FIG. 7 is a schematic cross-sectional view taken along line B-B′ of FIG. 1. FIG. 7 schematically illustrates areas adjacent to the edge of the display device 10. FIG. 7 illustrates a partial structure of the base layer BSL and the backplane layer BP without illustrating the light-emitting-element layer EML, for convenience of explanation.

Referring to FIG. 7, the first backplane layer BP1 may comprise a pad PAD and a pad insulating layer PINS.

The pad PAD may be electrically connected to lines (for example, data lines) of the display device 10. The lines may be formed by one or more among the conductive layers provided to form the first backplane layer BP1. The pad PAD may comprise one or more layers. The pad PAD may be formed by one or more among the conductive layers provided to form the first backplane layer BP1. However, the disclosure is not limited to a specific example.

The pad PAD may be disposed on a layer provided in the first backplane layer BP1, and may be covered with the pad insulating layer PINS. The pad insulating layer PINS allows a portion of the pad PAD to be exposed. In an area where the portion of the pad PAD is exposed, the pad PAD and a first pad connection line PCL1 may be electrically connected to each other. The first pad connection line PCL1 may be a side surface line.

A portion of the first pad connection line PCL1 may be formed on the second backplane layer BP2 provided as a rear surface of the base layer BSL. The first pad connection line PCL1 may be electrically connected to a second pad connection line PCL2 formed on the second backplane layer BP2.

The second backplane layer BP2 may comprise a first lower passivation layer PPVX1, a lower via layer PVIA, and a second lower passivation layer PPVX2. The second backplane layer BP2 may comprise the second pad connection line PCL2.

The second pad connection line PCL2 may be disposed on the first lower passivation layer PPVX1, and may electrically connect the first pad connection line PCL1 with the driving circuit component FPCB. For example, a portion of the second pad connection line PCL2 may be electrically connected to the first pad connection line PCL1. Another portion of the second pad connection line PCL2 may be connected to the driving circuit component FPCB by a conductive adhesive component CAM.

The first lower passivation layer PPVX1 may be disposed on the rear surface of the base layer BSL, and may comprise inorganic material. The lower via layer PVIA may be disposed on the first lower passivation layer PPVX1, and may comprise organic material. The second lower passivation layer PPVX2 may be disposed on the lower via layer PVIA, and may comprise inorganic material.

The conductive adhesive component CAM may be an anisotropic conductive film or anisotropic conductive paste. The driving circuit component FPCB may comprise a flexible circuit substrate. The driving circuit component FPCB may comprise a source driving circuit configured to supply data voltages to the data lines.

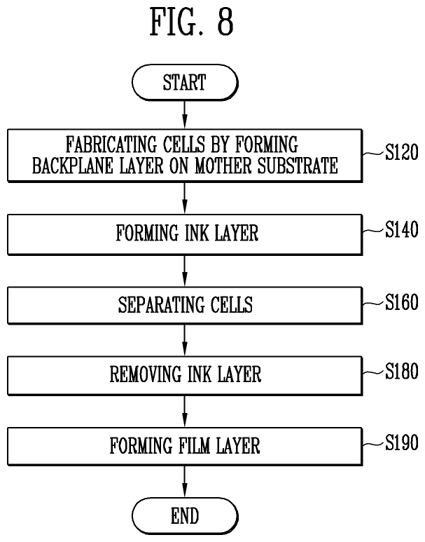

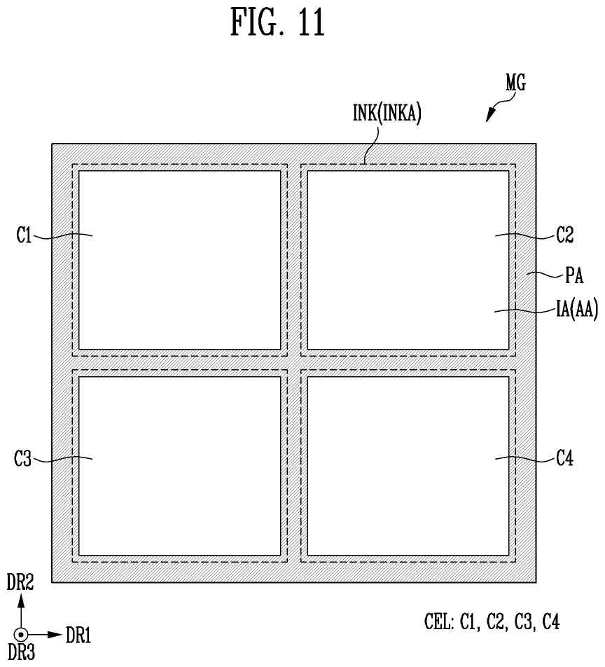

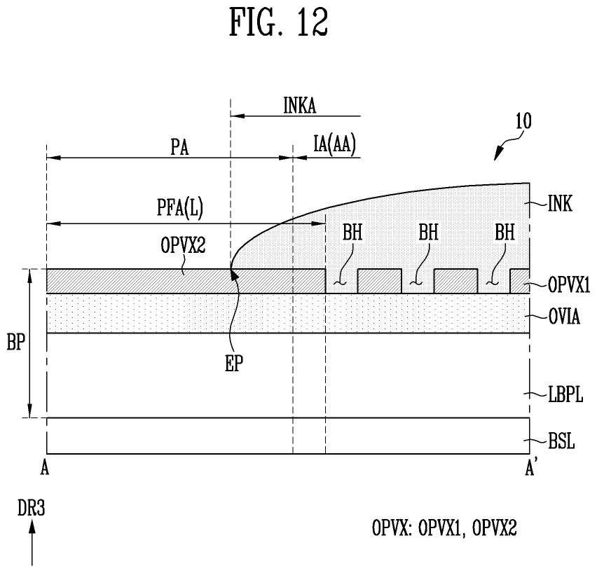

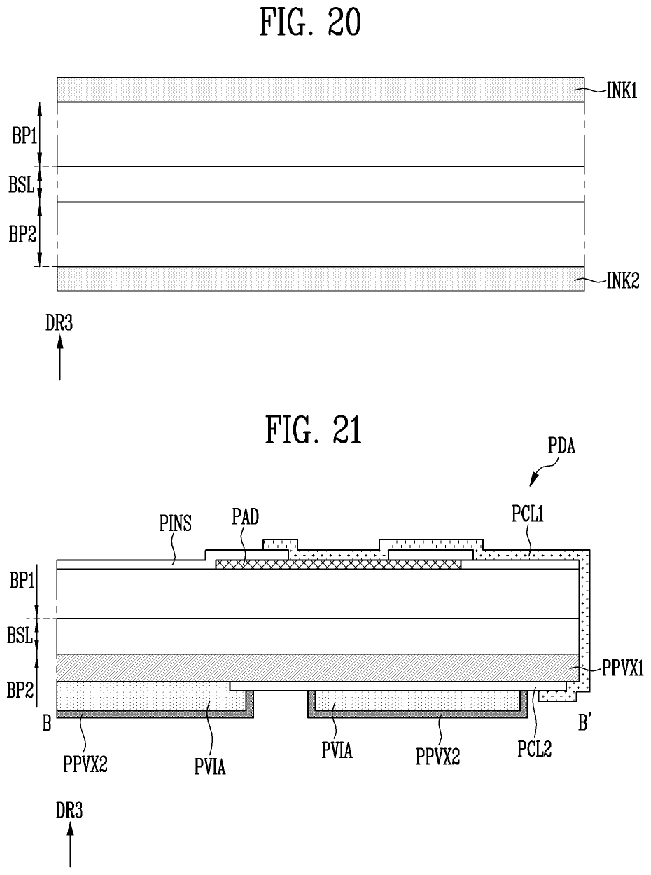

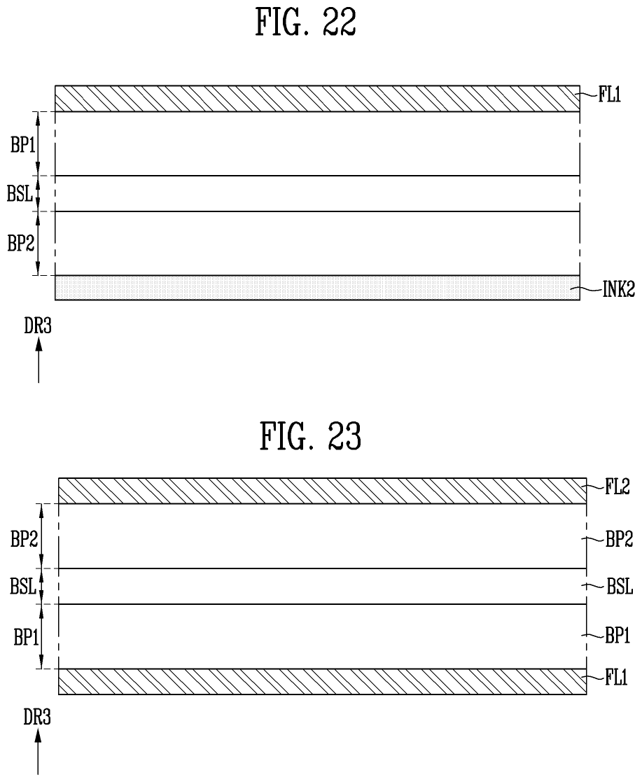

Hereinafter, a method of fabricating the display device in accordance with an embodiment will be described with reference to FIGS. 8 to 26. Description overlapping that of the embodiments described above will be simplified, or may not be repeated.

First, a method of fabricating the display device 10 in accordance with an embodiment will be described with reference to FIGS. 8 to 15.

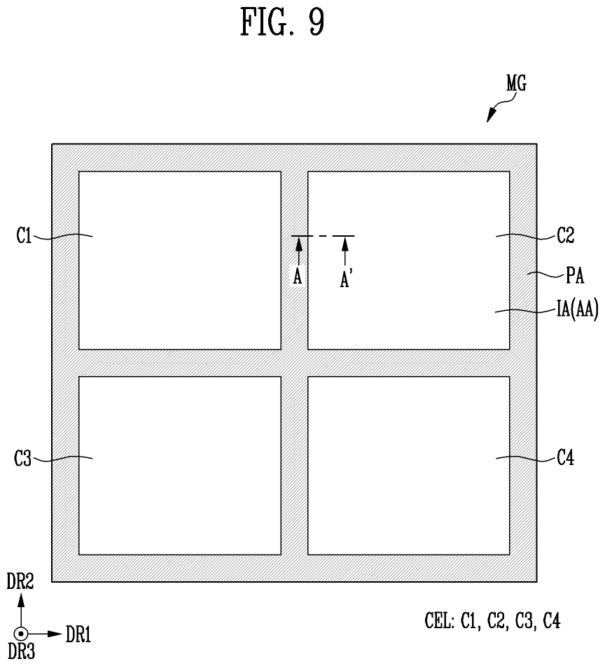

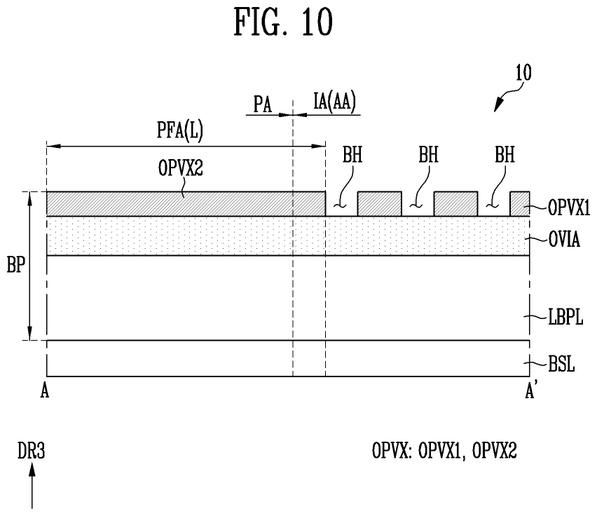

FIG. 8 is a flowchart illustrating the method of fabricating the display device 10 in accordance with an embodiment. FIGS. 9, 11, and 13 are schematic plan views illustrating, by process steps, the method of fabricating the display device 10 in accordance with an embodiment. FIGS. 10, 12, 14, and 15 are schematic cross-sectional views illustrating, by process steps, the method of fabricating the display device 10 in accordance with an embodiment. FIGS. 10, 12, and 14 are schematic cross-sectional views each illustrating a cross-sectional area taken along line A-A′ of FIG. 9, and may illustrate an area corresponding to a cross-sectional area taken along line A-A′ defined in FIG. 1.

In an embodiment, the backplane layer BP may refer to the first backplane layer BP1 described above.

Referring to FIG. 8, the method of fabricating the display device 10 in accordance with an embodiment may comprise step S120 of fabricating cells by forming backplane layer on mother substrate, step S140 of forming an ink layer, step S160 of separating the cells from each other, step S180 of removing the ink layer, and step S190 of forming a film layer.

Referring to FIGS. 8 to 10, at step S120 of fabricating cells by forming backplane layer on mother substrate, the backplane layer BP may be formed on the mother substrate MG. Therefore, cells CEL may be formed (or defined) in each of areas of the mother substrate MG. The mother substrate MG may be a base layer BSL for the backplane layer BP of each of the cells CEL.

In an embodiment, the mother substrate MG may comprise the base layer BSL for forming each of the cells CEL. The bother board MG may be a component for simultaneously fabricating two or more display devices 10. In an embodiment, the mother substrate MG may be divided into parts to form the respective base layers BSL for the cells CEL.

In a phase, the cells CEL may comprise a first cell C1, a second cell C2, a third cell C3, and a fourth cell C4. The number of cells CEL is not particularly limited.

In a phase, the base layer BSL may be prepared, and conductive layers and insulating layers for forming the backplane layer BP on the base layer BSL may be patterned. The conductive layers and the insulating layers may be formed through a selectable patterning process (for example, a photolithography process or the like) using a mask.

In a phase, the lower backplane layer LBPL may be formed on the base layer BSL. The outer via layer OVIA may be formed on the lower backplane layer LBPL. The first outer passivation layer OPVX1 and the second outer passivation layer OPVX2 may be patterned on the outer via layer OVIA.

In a phase, the outer passivation layer OPVX may form holes BH through which the outer via layer OVIA is exposed. Here, the holes BH may be formed in an internal area IA without being disposed in the peripheral area PA. Here, the internal area IA may be an area to be defined as the active area AA as the light emitting element LE is disposed through subsequent processes.

In a phase, the second outer passivation layer OPVX2 may be patterned to cover the peripheral area PA and a portion of the internal area IA, and may thus define the peripheral cover area PFA. Here, the second outer passivation layer OPVX2 my cover the overall surface of the peripheral area PA. The holes BH may not be formed in the peripheral area PA.

In an embodiment, the peripheral area PA may correspond to an edge area of each of the cells CEL. For example, the peripheral area PA may comprise areas between the adjacent cells CEL, and may comprise an outermost area of the cells CEL.

For example, the holes BH may not be formed in the edge area of each of the cells CEL. The holes BH may not be formed in the area between the adjacent cells CEL.

Referring to FIGS. 8, 11, and 12, at step S140 of forming the ink layer, the ink layer INK may be formed on the outer via layer OVIA and the outer passivation layer OPVX.

In a phase, the ink layer INK may cover the overall surface of the active area AA. The ink layer INK may cover the hole BH. The ink layer INK may cover the active area AA and a portion of the peripheral area PA. In a plan view, the ink layer INK may overlap the active area AA and the peripheral area PA. The ink layer INK may overlap the peripheral cover area PFA, in a plan view.

In an embodiment, an area where the ink layer INK is disposed may be defined as an ink area INKA. The ink area INKA may be determined, based on an end EP of the ink layer INK. The end EP of the ink layer INK may be disposed in the peripheral area PA. The end EP of the ink layer INK may contact the second outer passivation layer OPVX2. The end EP may refer to an outermost portion of the ink layer INK, based on a direction from the internal area IA toward the peripheral area PA.

Experimentally, in the case where a hole structure is formed in the peripheral area PA, the end EP of the ink layer INK may be disposed adjacent to the hole structure. Due to a step difference formed by the hole structure, there may be a risk of disconnection of a portion of the ink layer INK around the end EP. However, in an embodiment, the end EP of the ink layer INK may be formed to extend to the peripheral area PA, and the second outer passivation layer OPVX2 that covers the overall surface of the peripheral area PA may not form the hole BH. Hence, the foregoing risk may be prevented from occurring. In a case where a portion of the ink INK is damaged, a portion of the ink layer INK may remain. The visibility of the display device 10 may deteriorate. Consequently, in an embodiment, a defect may be prevented from occurring during the process of fabricating the display device 10, so that the visibility of the display device 10 can be enhanced.

In a phase, the ink layer INK may not contact the outer via layer OVIA in the peripheral area PA. For example, the ink layer INK may be spaced apart from the outer via layer OVIA by the second outer passivation layer OPVX2 in the peripheral area PA.

In a phase, the ink layer INK may contact the outer via layer OVIA in the active area AA. For example, the ink layer INK may contact the outer via layer OVIA in the hole BH in the active area AA.

In an embodiment, the ink layer INK may function as a protective layer for protecting an internal structure of each of the cells CEL during a subsequent process of separating the cells CEL from each other. In an embodiment, the ink layer INK may comprise acrylic material. For example, the ink layer INK may comprise an acrylic oligomer. In an embodiment, material for forming the ink layer INK may be an acrylic oligomer formed by applying UV light to a monomer and converting the monomer to an oligomer. However, the disclosure is not limited to the foregoing. The ink layer INK may comprise various oligomers and the like within the spirit and the scope of the disclosure.

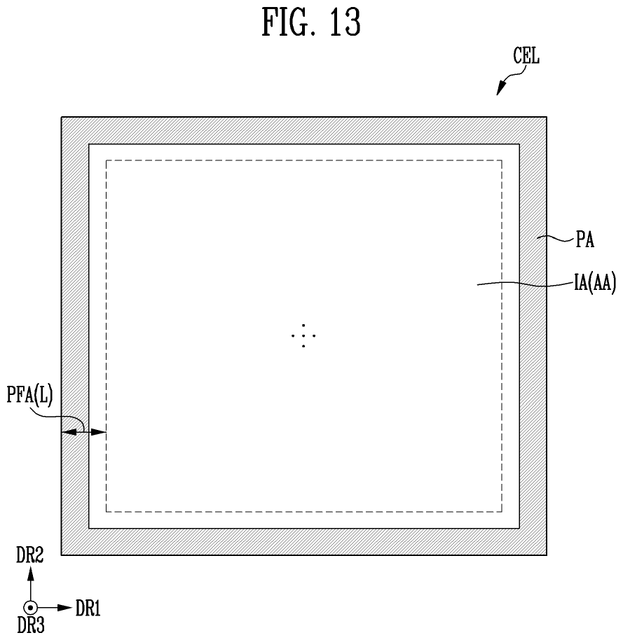

Referring to FIGS. 8 and 13, at step S160 of separating the cells, the cells CEL may be separated from each other on the mother substrate MG, thus forming separate panels.

In a phase, the cells CEL on the mother substrate MG may be cut. For example, in a phase, a scribing process may be performed to separate the cells CEL from each other. However, the disclosure is not limited to the foregoing example. In a phase, various processes for cutting the cells CEL may be used.

In a phase, the second outer passivation layer PVX2 in the cells CEL may be cut. In an embodiment, the second outer passivation layer OPVX2 may be cut, and the first outer passivation layer OPVX1 may not be cut.

In an embodiment, a position of a cutting line along which the cutting process is performed may be formed in the peripheral area PA disposed between the cells CEL. In an embodiment, the cutting line along which the cutting process is performed may not overlap the ink layer INK, in a plan view.

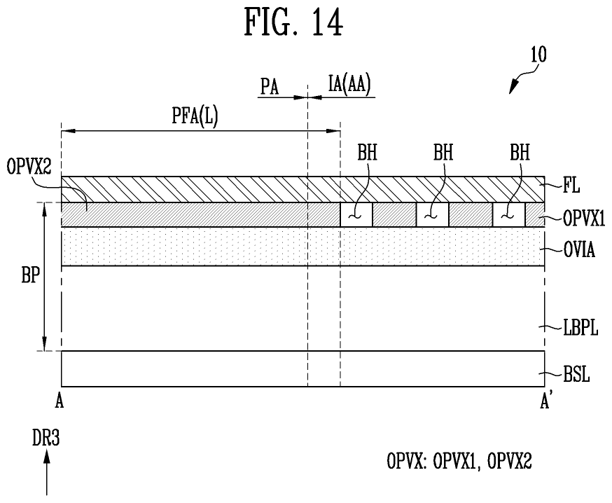

Referring to FIGS. 8 and 14, step S160 of removing the ink layer, the ink layer INK may be removed. The ink layer INK may be removed in various ways. A method of removing the ink layer INK is not limited to a specific example.

The process to be performed in a phase may be referred to as a peeling process.

In a phase, the outer passivation layer OPVX may be exposed by removing the ink layer INK. The outer via layer OVIA may be exposed through the hole BH.

Referring to FIGS. 8 and 14, at step S190 of forming the film layer, the film layer FL may cover the outer passivation layer OPVX and the outer via layer OVIA.

In an embodiment, the film layer FL may comprise various materials. For example, the film layer FL may comprise polyimide. However, the disclosure is not limited to the foregoing.

In an embodiment, the film layer FL may be a protective component for packaging a stacked structure comprising the backplane layer BP. For example, the stacked structure comprising the backplane layer BL covered with the film layer FL may be transferred to subsequent processing equipment.

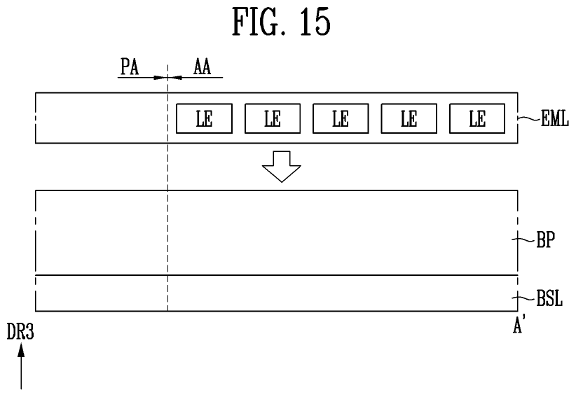

Referring to FIG. 15, the method of fabricating the display device 10 may further comprise the step of forming the light-emitting-element layer EML on the backplane layer BP. FIG. 15 is a schematic cross-sectional view illustrating the step of forming the light-emitting-element layer in accordance with an embodiment.

In an embodiment, the film layer FL may be removed from the previously-fabricated backplane layer BP, and the light-emitting-element layer EML comprising the light emitting elements LE may be provided on the backplane layer BP.

For example, the light emitting elements LE may be disposed on the backplane layer BP so that the active area AA may be formed. As described above, the light emitting elements LE may be disposed in the internal area IA so that the active area AA may be defined.

In a phase, the light emitting elements LE may be transferred onto the backplane layer BP in various ways. For example, the light emitting elements LE may be transferred using at least one of apparatuses each using at least one of a transfer scheme using a stamp, a transfer scheme using a laser, a transfer scheme using electrostatic force, a transfer scheme using magnetic force and electromagnetic force, and a transfer scheme using adhesive. However, the disclosure is not limited to a specific example. In an embodiment, the light emitting elements LE may be disposed on the backplane layer BP by a scheme comprising an operation of forming two or more electrode structures, an operation of supplying the light emitting elements LE onto the electrode structures, and an operation of forming an electric field between the electrode structures.

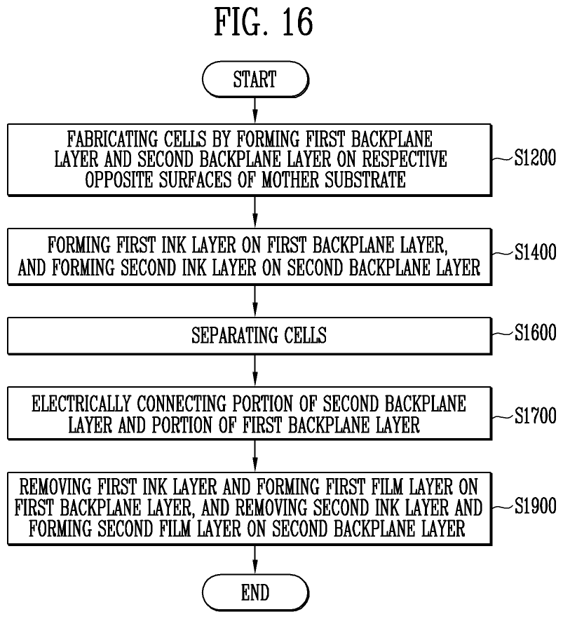

A method of fabricating the display device 10 in accordance with an embodiment will be described with reference to FIGS. 16 to 24. Description overlapping that of the embodiments described above will be simplified, or may not be repeated.

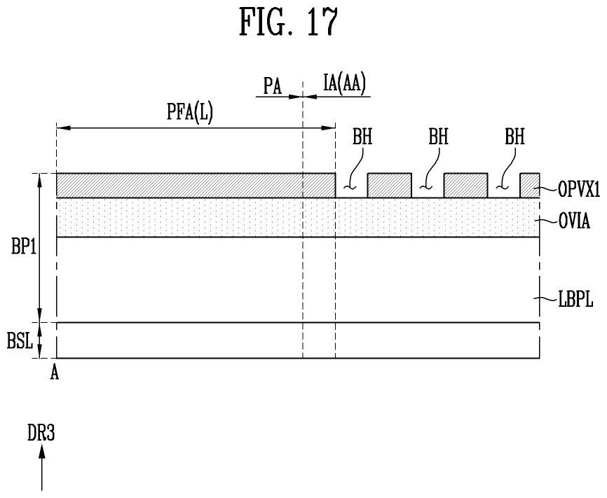

FIG. 16 is a flowchart illustrating the method of fabricating the display device 10 in accordance with an embodiment. FIGS. 17 to 24 are schematic cross-sectional views illustrating, by process phases, the method of fabricating the display device 10 in accordance with an embodiment.

The method of fabricating the display device 10 in accordance with an embodiment may comprise step S1200 of fabricating cells by forming a first backplane layer and a second backplane layer on respective opposite surfaces of mother substrate, step S1400 of forming a first ink layer on the first backplane layer and forming a second ink layer on the second backplane layer, step S1600 of separating the cells from each other, step S1700 of electrically connecting a portion of the second backplane layer and a portion of the first backplane layer to each other, and step S1900 of removing the first ink layer and forming a first film layer on the first backplane layer, and removing the second ink layer and forming a second film layer on the second backplane layer.

Referring to FIGS. 16 to 18, at step S1200 of fabricating cells by forming a first backplane layer and a second backplane layer on respective opposite surfaces of mother substrate, the first backplane layer BP1 may be formed on a first surface of the base layer BSL, and the second backplane layer BP2 may be formed on a second surface of the base layer BSL.

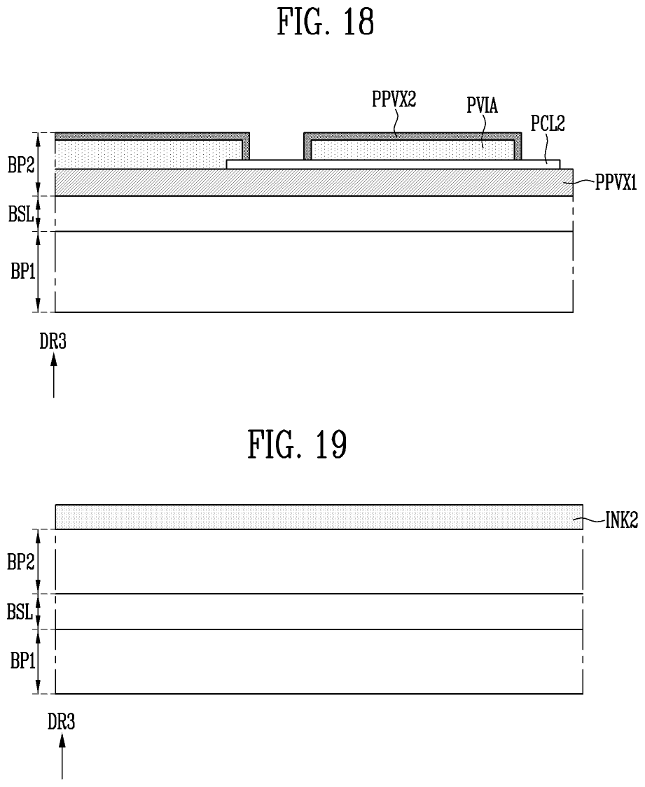

For example, the lower backplane layer LBPL is formed on the first surface of the base layer BSL, and the outer via layer OVIA and the outer passivation layer OPVX may be formed (refer to FIG. 17). After the first backplane layer BP1 is formed, a structure comprising the base layer BSL and the first backplane layer BP1 is reversed (for example, turned upside down) so that the first backplane layer BP1 is oriented downward, and thereafter the second backplane layer BP2 may be formed (refer to FIG. 18).

In an embodiment, after the first backplane layer BP1 is formed, a sacrificial layer may be formed on the first backplane layer BP1 before the structure comprising the base layer BSL and the first backplane layer BP1 is turned upside down. The sacrificial layer may be a layer for protecting the first backplane layer BP1, and may be removed during a subsequent process before a first ink layer INK1 is disposed.

In a phase, to form the second backplane layer BP2, the first lower passivation layer PPVX1 may be disposed on the second surface of the base layer BSL, and the second pad connection line PCL2 may be disposed on the first lower passivation layer PPVX1. The second pad connection line PCL2 may be exposed by patterning the lower via layer PVIA. The second lower passivation layer PPVX2 may be formed on the lower via layer PVIA.

Depending on the embodiment, in a phase, the pad PAD and the pad insulating layer PINS may be formed in case that the first backplane layer BP1 is formed. The pad PAD may be electrically connected to a portion of the second backplane layer BP2 during a subsequent process.

Referring to FIGS. 16, 19, and 20, at step S1400 of forming the first ink layer on the first backplane layer and forming second ink layer on the second backplane layer, the first ink layer INK1 may be formed on the first backplane layer BP1, and a second ink layer INK2 may be formed on the second backplane layer BP2. The first ink layer INK1 may be an ink layer INK which covers the first backplane layer BP1, and may comprise substantially the same characteristics as the ink layer INK described above. The second ink layer INK2 may be an ink layer INK which covers the second backplane layer BP2.

In a phase, the second ink layer INK2 may be disposed on the second backplane layer BP2 and, thereafter, a structure in which the first backplane layer BP1, the base layer BSL, the second backplane layer BP2, and the second ink layer INK2 are successively disposed may be reversed (for example, turned upside down) so that the second ink layer INK2 can be oriented downward. The first ink layer INK1 may be disposed on the first backplane layer BP1.

Referring to FIG. 16, at step S1600 of separating the cells from each other, the cells CEL may be physically separated from each other. Hence, the cells CEL which are individually separated from each other may be provided.

Referring to FIGS. 16 and 21, at step S1700 of electrically connecting a portion of the second backplane layer and a portion of the first backplane layer to each other, the first pad connection line PCL1 may be formed so that the pad PAD and the second pad connection line PCL2 can be electrically connected to each other. The process performed in a phase may be a process of electrically connecting the pad PAD and other lines to each other. FIG. 21 illustrates the process that is performed for an area comprising the pad area PDA.

In a phase, the first pad connection line PCL1 may have a portion that covers a side surface of the base layer BSL, and may electrically connect a portion (for example, the pad PAD) of the first backplane layer BP1 and a portion (for example, the second pad connection line PCL2) of the second backplane layer BP2 to each other. The second pad connection line PCL2 may be a line to be electrically connected to the driving circuit component FPCB. Consequently, the pad PAD may be electrically connected to the driving circuit component FPCB.

The process to be performed in a phase may be referred to as a side surface process.

A time point at which the process in a phase is performed is not particularly limited, and may be appropriately changed depending on the process environment.

Referring to FIGS. 16, 22, and 23, at step S1900 of removing the first ink layer and forming the first film layer on the first backplane layer, and removing the second ink layer and forming the second film layer on the second backplane layer, a first film layer FL1 may be formed on the first backplane layer BP1, and a second film layer FL2 may be formed on the second backplane layer BP2. The first film layer FL1 may be a film layer FL which covers the first backplane layer BP1, and may comprise substantially the same characteristics as the film layer FL described above. The second film layer FL2 may be a film layer FL which covers the second backplane layer BP2, and may comprise substantially the same characteristics as the film layer FL described above. Hence, the structure in which the first backplane layer BP1 and the second backplane layer BP2 are formed may be packaged.

In a phase, the first film layer FL1 is disposed after the first ink layer INK1 is removed from the first backplane layer BP1, and thereafter, the structure in which the second ink layer INK2, the second backplane layer BP2, the base layer BSL, the first backplane layer BP1, and the first film layer FL1 are successively disposed may be reversed (for example, turned upside down) so that the second backplane layer BP2 can be oriented downward. After the second ink layer INK2 is removed from the second backplane layer BP2, the second film layer FL2 may be disposed on the second backplane layer BP2.

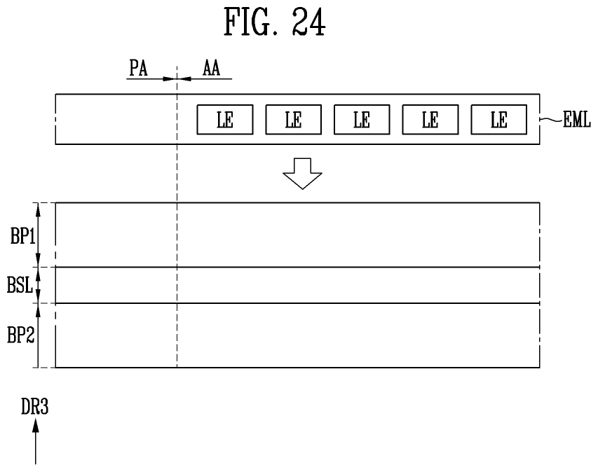

Referring to FIG. 24, the method of fabricating the display device 10 may further comprise the step of forming the light-emitting-element layer EML on the first backplane layer BP1 on the base layer BSL.

In an embodiment, the first film layer FL1 may be removed from the previously-fabricated first backplane layer BP1, and the light-emitting-element layer EML comprising the light emitting elements LE may be provided on the first backplane layer BP1.

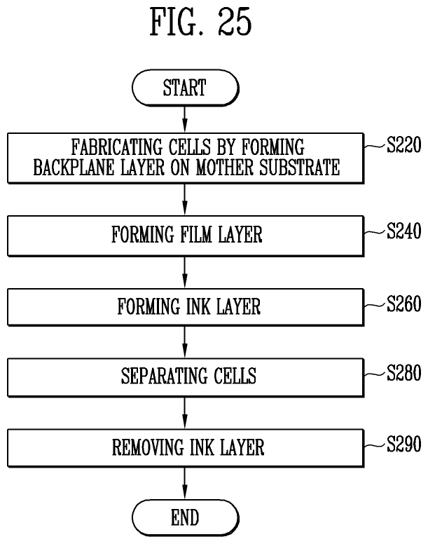

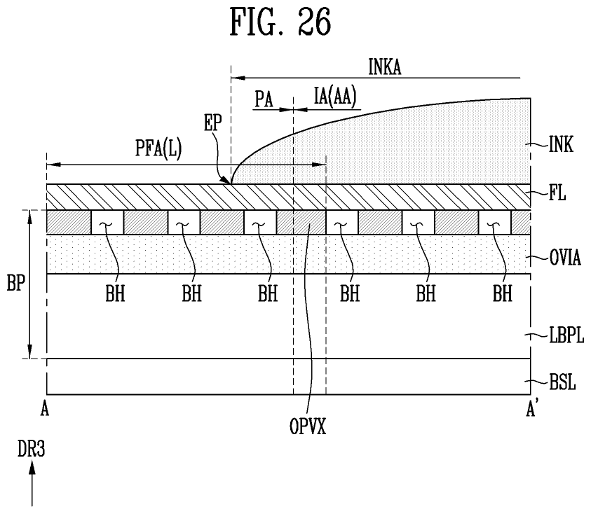

A method of fabricating the display device 10 in accordance with an embodiment will be described with reference to FIGS. 25 and 26. Description overlapping that of the embodiments described above will be simplified, or may not be repeated.

FIG. 25 is a flowchart illustrating the method of fabricating the display device 10 in accordance with an embodiment. FIG. 26 is a schematic cross-sectional view illustrating processing steps of the method of fabricating the display device in accordance with an embodiment.

Referring to FIG. 25, the method of fabricating the display device 10 in accordance with an embodiment may comprise step S220 of fabricating cells by forming a backplane layer on a mother substrate, step S240 of forming a film layer, step S260 of forming an ink layer, step S280 of separating the cells from each other, and step S290 of removing the ink layer.

The method of fabricating the display device 10 in accordance with an embodiment may be different from the method of the display device 10 in accordance with an embodiment or another embodiment in that the film layer FL is formed before the ink layer INK is formed.

Referring to FIGS. 25 and 26, after the film layer FL is disposed on the outer via layer OVIA and the outer passivation layer OPVX, the ink layer INK may be disposed. For example, the film layer FL may cover the peripheral area PA and the internal area IA, so that the film layer FL may cover the entirety of the hole BH. Hence, an upper surface of the film layer FL may form a base area in which the ink layer INK is formed. Because the film layer FL does not comprise a hole structure, a separate stepped structure (for example, a hole structure or the like) may not be formed. There is no risk of disconnection of a portion of the ink layer INK.

According to an embodiment, the outer passivation layer OPVX may form the hole BH in the peripheral area PA. For example, at step S220 of fabricating cells by forming a backplane layer on a mother substrate, the outer passivation layer OPVX allows at least a portion of the outer via layer OVIA in the peripheral area PA and the internal area IA to be exposed.

For example, the hole BH may comprise an internal hole formed in the internal area IA, and a peripheral hole formed in the peripheral area PA.

In an embodiment, the end EP of the ink layer INK may overlap the film layer FL and the hole BH, in a plan view.

As described above, because the ink layer INK is formed after the film layer FL is formed, there is no risk of disconnection of the ink layer INK even in the case where the hole BH is formed in the peripheral area PA. Compared to the method of fabricating the display device 10 in accordance with an embodiment or another embodiment, the number of holes BH that can be formed may be increased. Hence, gas in the backplane layer BP can be more efficiently exhausted.

According to an embodiment, after the ink layer INK is formed on the film layer FL, the cells CEL may be separated from each other. Thereafter, the ink layer INK may be removed. Consequently, a structure comprising the backplane layer BP may be packaged.

Various embodiments may provide a display device capable of eliminating a risk caused by outgassing, and capable of preventing a residue phenomenon from occurring due to remnants of a structure used during a process of fabricating the display device, and may provide a method of fabricating the display device.

While various embodiments have been described above, those skilled in the art will appreciate that various modifications, additions and substitutions are possible, without departing from the scope and spirit of the disclosure.

Therefore, the embodiments disclosed in this specification are only for illustrative purposes rather than limiting the technical spirit of the disclosure. The scope of the disclosure is also defined by the accompanying claims.

What is claimed is:

1. A display device comprising:
an active area and a peripheral area adjacent to at least a portion of the active area;
a base layer;
a backplane layer disposed on the base layer; and
a light-emitting-element layer disposed on the backplane layer, and comprising a light emitting element, wherein
the backplane layer comprises:
a lower backplane layer;
an outer via layer disposed on the lower backplane layer; and
an outer passivation layer disposed on the outer via layer, and
the outer passivation layer comprises:
a first outer passivation layer exposing the outer via layer through a hole in the active area; and
a second outer passivation layer not exposing the outer via layer in the peripheral area.

2. The display device according to claim 1, wherein
the second outer passivation layer is disposed in a peripheral cover area,
a portion of the peripheral cover area overlaps the peripheral area, in a plan view, and
another portion of the peripheral cover area overlaps the active area, in a plan view.

3. The display device according to claim 2, wherein the second outer passivation layer comprises:
a body covering an overall surface of the peripheral area; and
an extension part extending from the body and disposed in the active area.

4. The display device according to claim 2, wherein the peripheral cover area is formed along an edge of the display device.

5. The display device according to claim 2, wherein a width of the peripheral cover area is in a range of about 100 μm to about 800 μm.

6. The display device according to claim 1, wherein
the lower backplane layer comprises a lower via layer, and a lower passivation layer disposed on the lower via layer,
each of the outer passivation layer and the lower passivation layer comprises an inorganic material,
each of the outer via layer and the lower via layer comprises an organic material, and
the lower passivation layer forms a lower hole exposing the lower via layer.

7. A method of fabricating a display device, comprising:
fabricating cells including forming a backplane layer on a substrate;
forming an ink layer on the backplane layer; and
separating the cells from each other, wherein
each of the cells comprises an internal area, and a peripheral area adjacent to at least a portion of the internal area,
the forming of the backplane layer comprises forming an outer via layer, and forming an outer passivation layer on the outer via layer,
the forming of the outer passivation layer comprises forming a first outer passivation layer, and forming a second outer passivation layer,
the forming of the first outer passivation layer comprises forming a hole exposing the outer via layer, in the first outer passivation layer in the internal area, and
the forming of the second outer passivation layer comprises covering the outer via layer with the second outer passivation layer without exposing the outer via layer in the peripheral area.

8. The method according to claim 7, wherein the second outer passivation layer covers an overall surface of the peripheral area.

9. The method according to claim 7, wherein the peripheral area corresponds to an edge of each of the cells.

10. The method according to claim 7, wherein
the ink layer comprises an end based on a direction from the internal area toward the peripheral area, and
the end overlaps the peripheral area, in a plan view.

11. The method according to claim 10, wherein the end does not contact the outer passivation layer in the peripheral area, and contacts the second outer passivation layer.

12. The method according to claim 11, wherein the end contacts the outer passivation layer in the hole in the internal area.

13. The method according to claim 7, wherein the ink layer comprises an acrylic oligomer.

14. The method according to claim 7, further comprising:
removing the ink layer; and
forming a film layer on the outer passivation layer.

15. The method according to claim 7, wherein
the separating of the cells from each other comprises forming a base layer of each of the cells on the substrate,
the forming of the backplane layer comprises forming a first backplane layer on a surface of the base layer, and forming a second backplane layer on a rear surface of the base layer,
the method further comprises forming a light-emitting-element layer comprising a light emitting element on the first backplane layer,
the first backplane layer comprises a pad and a pixel circuit configured to drive the light emitting element, and
the second backplane layer comprises a line that electrically connects a driving circuit component with the pad.

16. The method according to claim 15, wherein
the forming of the ink layer comprises forming a first ink layer on the first backplane layer, and forming a second ink layer on the second backplane layer;
the method further comprises removing the first ink layer and forming a first film layer on the first backplane layer; and
removing the second ink layer and forming a second film layer on the second backplane layer.

17. The method according to claim 16, wherein the first film layer and the second film layer package a stacked structure comprising the first backplane layer and the second backplane layer.

18. A method of fabricating a display device, comprising:
fabricating cells by forming a backplane layer on a substrate;
forming a film layer on the backplane layer;
forming an ink layer on the film layer; and
separating the cells from each other, wherein
the forming of the backplane layer comprises forming an outer via layer, and forming an outer passivation layer on the outer via layer,
the forming of the outer passivation layer comprises forming a hole exposing the outer via layer, in the outer passivation layer, and
the forming of the film layer comprises covering an entirety of the hole with the film layer.

19. The method according to claim 18, wherein the film layer forms a base surface that disposes the ink layer on the base surface, and the ink layer is separated from the backplane layer by the film layer.

20. The method according to claim 18, wherein
each of the cells comprises an internal area and a peripheral area, and
the hole comprises an internal hole disposed in the internal area, and a peripheral hole disposed in the peripheral area.
